(19) United States
(12) Patent Application Publication
(10) Pub. No.: US 2026/0293052 A1
(43) Pub. Date: Sep. 24, 2026

(54) Radiator and Electronic Apparatus

(71) Applicant: Telefonaktiebolaget LM Ericsson (publ), Stockholm (SE)

(72) Inventors: Xiu Shi, Beijing (CN); Min Yin, Beijing (CN); Zhenzhen Liu, Beijing (CN); Siyuan Jia, Beijing (CN)

(21) Appl. No.: 19/473,989

(22) PCT Filed: May 10, 2023
(86) PCT No.: PCT/CN2023/093231

§ 371 Date: Oct. 9, 2025

(51) Int. Cl. H05K 7/20

(52) U.S. Cl. CPC H05K 7/20318; H05K 7/20309; H05K 7/20327

(57) ABSTRACT

The present disclosure is related to a radiator and an electronic apparatus. The radiator includes an evaporator, a condenser, at least one liquid working fluid pipe, and two or more gaseous working fluid pipes. The at least one liquid working fluid pipe and the two or more gaseous working fluid pipes are arranged to form more than one circulation loop thermosyphons together with the evaporator and the condenser.

### TECHNICAL FIELD

The present disclosure is related to the field of passive liquid cooler, and in particular, to a radiator and an electronic apparatus.

### BACKGROUND

With electronic component power consumption increasing, the traditional air cooling method is facing challenge. For example, the next generation switch chip used in current electronic product will come to several hundred watts on a single chip. This power consumption level exceeds the cooling capacity of current air cooling method with local heat sink solution.

On the other hand, the whole society is advocating energy saving and emission reduction. Designers are trying every possible to limit the power consumption of the developing products.

There is a need for a cooling method which has a high cooling capacity and better cooling efficiency. Liquid cooling is recognized in the industry as an advanced cooling method which has both the merits.

However, a device involving liquid cooling in prior art can not sufficiently meet requirements of the rapid development of the electronic device.

### SUMMARY

According to a first aspect of the present disclosure, a radiator is provided. The radiator includes: an evaporator arranged to evaporate liquid working fluid in the evaporator to form gaseous working fluid; a condenser configured to condense the gaseous working fluid into the liquid working fluid; at least one liquid working fluid pipe, arranged to couple the condenser with the evaporator and to convey the liquid working fluid to the evaporator from the condenser; andtwo or more gaseous working fluid pipes, arranged to couple the condenser with the evaporator and to convey the gaseous working fluid to the condenser from the evaporator,
wherein the at least one liquid working fluid pipe and the two or more gaseous working fluid pipes are arranged to form more than one circulation loop thermosyphons together with the evaporator and the condenser.

In some embodiments, the condenser includes a base plate having at least one surface higher than a bottom of the evaporator.

In some embodiments, the evaporator includes: an evaporator housing main body defining a first cavity therein and having at least one evaporator inlet; anda raised portion, on the top of the evaporator housing main body, defining a second cavity therein in fluid communication with the first cavity and being disposed with two or more evaporator outlets; wherein the two or more gaseous working fluid pipes are connected to the evaporator outlets of the raised portion respectively, so that the gaseous working fluid in the second cavity is expelled to the two or more gaseous working fluid pipes 40 via the evaporator outlets.

In some embodiments, a horizontal section area of the raised portion is less than that of the evaporator housing main body.

In some embodiments, the at least one liquid working fluid pipe is connected to the evaporator inlet of the evaporator housing main body, so as to convey the liquid working fluid to the first cavity.

In some embodiments, the at least one liquid working fluid pipe includes one liquid working fluid pipe connected to a condenser outlet in the middle of the condenser; and the two or more gaseous working fluids pipes include two gaseous working fluid pipes connected respectively to condenser inlets of the condenser at both ends thereof.

In some embodiments, the two gaseous working fluid pipes 40 include a first gaseous working fluid pipe and a second gaseous working fluid pipe; the condenser inlets include a first condenser inlet and a second condenser inlet, the first gaseous working fluid pipe, the first condenser inlet, the condenser outlet, and the one liquid working fluid pipe constitute at least part of a first circulation loop thermosyphon, and the second gaseous working fluid pipe, the second condenser inlet, the condenser outlet and the one liquid working fluid pipe constitute at least part of the second circulation loop thermosyphon.

In some embodiments, the at least one liquid working fluid pipe includes two liquid working fluid pipes connected to condenser outlets in the middle of the condenser, and the two or more gaseous working fluid pipes include two gaseous working fluid pipes respectively connected to condenser inlet at either end of the condenser.

In some embodiments, the condenser outlets include a first condenser outlet and a second condenser outlet, and the two liquid working fluid pipes include a first liquid working fluid pipe connected to the first condenser outlet and a second liquid working fluid pipe connected to the second condenser outlet; the condenser inlets include a first condenser inlet and a second condenser inlet, and the two gaseous working fluid pipes include a first gaseous working fluid pipe connected to the first condenser inlet and a second gaseous working fluid pipe connected the second condenser inlet; wherein the first gaseous working fluid pipe, the first condenser inlet, the first condenser outlet and the first liquid working fluid pipe constitute at least part of a third circulation loop thermosyphon, and the second gaseous working fluid pipe, the second condenser inlet, the second condenser outlet and the second liquid working fluid pipe constitute at least part of a fourth circulation loop thermosyphon.

In some embodiments, the condenser has a condenser cavity and a plurality of internal condensation fins configured to space from each other within the condenser cavity, and a plurality of external condensation fins configured to space from each other outside of the condenser cavity, the plurality of internal condensation fins and the plurality of external condensation fins being mounted respectively on opposite side surface of the base plate of the condenser.

In some embodiments, the plurality of internal condensation fins are arranged in a polygonal shape, so as to have a cut area with respect to the condenser and such that at least one side of the polygonal shape is oblique with respect to a direction in which the plurality of internal condensation fins are arranged.

In some embodiments, the condenser includes a condenser outlet in the base plate of the condenser, so that the at least one liquid working fluid pipe is connected to the condenser outlet among the plurality of external condensation fins.

In some embodiments, a dropped cavity is provided in the base plate communicated and integrated with the condenser cavity, and the condenser outlet is open towards the dropped cavity.

In some embodiments, the evaporator includes a plurality of evaporation fins configured to space from each other within the first cavity of the evaporator housing main body.

In some embodiments, the plurality of evaporation fins are divided into sections by one or more channel so that the working fluid is capable of passing through the one or more channel to a space between adjacent ones of the plurality of evaporation fins.

In some embodiments, an extension direction of the one or more channels and that of the space are not parallel to each other, and/or the space between adjacent ones of the plurality of evaporation fins crosses and are in fluid communication with at least one of the one or more channels.

In some embodiments, at least one of the one or more channels opens towards the evaporator inlet, connected to the at least one liquid working fluid pipe, of the evaporator housing main body.

According to a third aspect of the present disclosure, an electronic apparatus including a radiator of the first aspect is provided.

In some embodiment, the electronic apparatus further includes a fan, wherein the fan is arranged to abut against the condenser of the radiator and the condenser and the fan cover generally the same area in a horizontal plane.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and therefore are not to be considered limiting of its scope, the disclosure will be described with additional specificity and detail through use of the accompanying drawings.

FIG. 1 is a figure illustrating an exemplary radiator in operation state according to an embodiment of the present disclosure.

FIG. 2 is an exploded view illustrating an exemplary evaporator according to an embodiment of the present disclosure.

FIG. 3 is an exploded view illustrating an exemplary condenser according to an embodiment of the present disclosure.

FIG. 4 is a figure illustrating an exemplary electronic apparatus according to an embodiment of the present disclosure, in which part of a housing of the electronic apparatus is removed.

FIG. 5 is a graph illustrating relationships of a flow over temperature for radiators with one gaseous working fluid pipe in the prior art and with two gaseous working fluid pipes according to an embodiment of the present disclosure.

FIG. 6 is a figure illustrating an exemplary radiator in operation arrangement according to another embodiment of the present disclosure.

FIG. 7 is a figure illustrating an exemplary radiator in operation arrangement according to still another embodiment of the present disclosure.

FIG. 8 illustrates an evaporator according to an embodiment of the present disclosure, in which sectional views along line A-A and line B-B of the evaporator cavity are drawn to show a first cavity and a second cavity.

FIG. 9 illustrates a condenser according to an embodiment of the present disclosure without an external condensation fins for clarity.

### DETAILED DESCRIPTION

Hereinafter, the present disclosure is described with reference to embodiments shown in the attached drawings. However, it is to be understood that those descriptions are just provided for illustrative purpose, rather than limiting the present disclosure. Further, in the following, descriptions of known structures and techniques are omitted so as not to unnecessarily obscure the concept of the present disclosure.

Those skilled in the art will appreciate that the term “exemplary” is used herein to mean “illustrative,” or “serving as an example,” and is not intended to imply that a particular embodiment is preferred over another or that a particular feature is essential. Likewise, the terms “first”, “second”, “third”, “fourth,” and similar terms, are used simply to distinguish one particular instance of an item or feature from another, and do not indicate a particular order or arrangement, unless the context clearly indicates otherwise.

Conditional language used herein, such as “can,” “might,” “may,” “e.g.,” and the like, unless specifically stated otherwise, or otherwise understood within the context as used, is generally intended to convey that certain embodiments comprise, while other embodiments do not comprise, certain features, elements and/or states. Thus, such conditional language is not generally intended to imply that features, elements and/or states are in any way required for one or more embodiments or that one or more embodiments necessarily comprise logic for deciding, with or without author input or prompting, whether these features, elements and/or states are comprised or are to be performed in any particular embodiment. Also, the term “or” is used in its inclusive sense (and not in its exclusive sense) so that when used, for example, to connect a list of elements, the term “or” means one, some, or all of the elements in the list. Further, the term “each,” as used herein, in addition to having its ordinary meaning, can mean any subset of a set of elements to which the term “each” is applied.

The term “based on” is to be read as “based at least in part on.” The term “one embodiment” and “an embodiment” are to be read as “at least one embodiment.” The term “another embodiment” is to be read as “at least one other embodiment.” Other definitions, explicit and implicit, may be comprised below. In addition, language such as the phrase “at least one of X, Y and Z,” unless specifically stated otherwise, is to be understood with the context as used in general to convey that an item, term, etc. may be either X, Y, or Z, or a combination thereof.

The terminology used herein is for the purpose of describing particular embodiments only and is not intended to be limitation of example embodiments. As used herein, the singular forms “a”, “an”, and “the” are intended to comprise the plural forms as well, unless the context clearly indicates otherwise. It will be further understood that the terms “comprises”, “comprising”, “has”, “having”, “comprises” and/or “including”, when used herein, specify the presence of stated features, elements, and/or components etc., but do not preclude the presence or addition of one or more other features, elements, components and/or combinations thereof. It will be also understood that the terms “connect(s),” “connecting”, “connected”, etc. when used herein, just mean that there is an electrical or communicative connection between two elements and they can be connected either directly or indirectly, unless explicitly stated to the contrary.

Of course, the present disclosure may be carried out in other specific ways than those set forth herein without departing from the scope and essential characteristics of the disclosure.

Although a plurality of embodiments of the present disclosure will be illustrated in the accompanying drawings and described in the following Detailed Description, it should be understood that the disclosure is not limited to the disclosed embodiments, but instead is also capable of numerous rearrangements, modifications, and substitutions without departing from the present disclosure that as will be set forth and defined within the claims.

Further, please note that although the following description of some embodiments of the present disclosure is given in the context of electronic device/apparatus, the present disclosure is not limited thereto. In fact, as long as heat dissipation is involved, the inventive concept of the present disclosure may be applicable to any appropriate apparatus, etc.

Therefore, one skilled in the arts could readily understand that the terms used herein may also refer to their equivalents in any other infrastructure. For example, the term “User Equipment” or “UE” used herein may refer to a filter, a terminal device, a mobile terminal, a mobile station, a user device, a user terminal, a wireless device, a wireless terminal, or any other equivalents.

Further, the expression “A is connected or coupled to B” used herein may refer to that A may be coupled to B fluidly, mechanically, electrically, optically, electro-magnetically or in any other manner, either directly or indirectly, such that A can communicate with B or a fluid output from A may arrive at B, or vice versa.

Please note that although some embodiments will be described below in the context of one or more of the electronic device, the present disclosure is not limited thereto. In fact, the radiator according to some embodiments of the present disclosure may also be applicable to other apparatus than those described hereinafter.

There are generally two kinds of liquid cooling methods. One is active liquid cooling. The other is passive liquid cooling. The active liquid cooling device has dynamic part (pump) included which has the concern of low reliability and not power saving. The passive liquid cooling device has no dynamic part included which is high reliability. Network products always have high requirement on reliability. Thus, passive liquid cooling is a good selection.

A loop thermosyphon used includes an evaporator and a condenser which coupled with each other by a vapor pipe and a liquid pipe. The evaporator, the condenser, the vapor pipe and the liquid pipe form a closed loop space inside. The closed loop space is vacuumed and partly filled with a working fluid. The working fluid is vaporized in the evaporator when there is heat absorbing. The vapor is converted back into liquid phase of the working fluid after releasing heat in condenser. It is the density difference between liquid working fluid and vapour working fluid drives the working fluid circulation in loop thermosyphon. In a typical loop thermosyphon design, the liquid working fluid enters the evaporator on one side while the vapour working fluid is expelled from the evaporator on the opposite/adjacent side. And the vapour working fluid enters the condenser on one side while the liquid working fluid is expelled from the condenser on the opposite side. In this kind of loop thermosyphon, the working fluid flow resistance is high.

When a loop thermosyphon in horizontally installed equipment is used, due to there is small level difference between a condenser and an evaporator, the driving force to make working fluid cycling is weak. In this case, if the flow resistance inside the loop thermosyphon is high, the working fluid cycle in the loop thermosyphon will be very slow, which limits the cooling capacity of the loop thermosyphon.

The inventor realizes the limitation to the cooling capacity of the cooling device in which loop thermosyphon is implemented, and proposes a new radiator in the present disclosure. Embodiments of the radiator are listed for illustrating the inventive concept as below.

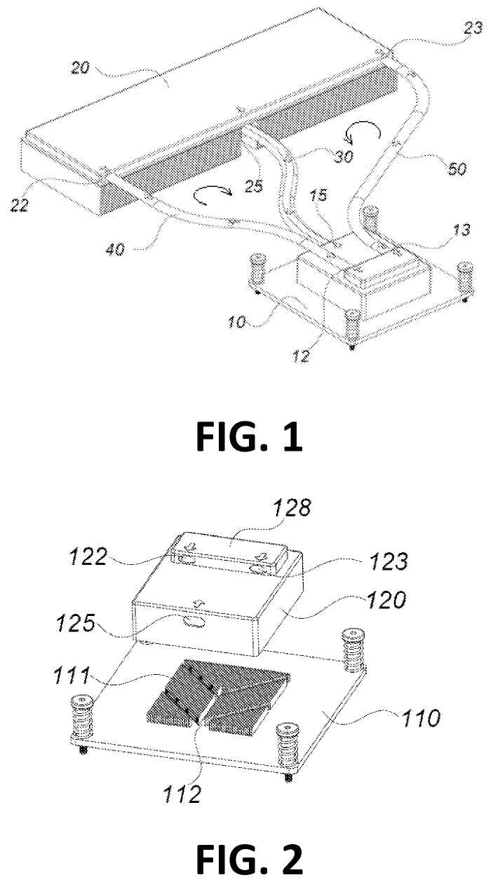

FIG. 1 is a schematic diagram illustrating an exemplary radiator according to an embodiment of the present disclosure. As shown in FIG. 1, the radiator includes an evaporator 10, a condenser 20 and connection between them. The evaporator 10 may be arranged to evaporate liquid working fluid in the evaporator 10 to form gaseous working fluid. The condenser 20 may be arranged to condense the gaseous working fluid into the liquid working fluid. The connection between the evaporator 10 and the condenser 20 includes one liquid working fluid pipe 30 and two gaseous working fluid pipes 40, 50. In another embodiment, however, the connection may include at least one, such as two or three, liquid working fluid pipe 30, and two or more, such as three or four, gaseous working fluid pipes 40, 50. The liquid working fluid pipe 30 may be arranged to couple the condenser 20 with the evaporator 10 and to convey the liquid working fluid to the evaporator 10 from the condenser 20. The gaseous working fluid pipes 40, 50 may be arranged to couple the condenser 20 with the evaporator 10 and to convey the gaseous working fluid to the condenser 20 from the evaporator 10. Embodiments below will be provided to illustrate examples of the connection of the radiator according to the present disclosure.

In the embodiment as shown in FIG. 1, the gaseous working fluid in the evaporator 10 is split into two parts, respectively entering the two gaseous working fluid pipes 40, 50. For the same situation including, such as, the same operating temperature of the working fluid, the same cavity volume of the radiator, etc., the flowing velocity of the gaseous working fluid in the radiator with two gaseous working fluid pipes 40, 50 is reduced by half, and a vapour flow resistance in the loop thermosyphon is greatly reduced, compared with a radiator with one gaseous working fluid pipe. For example, the vapour flow resistance in the gaseous working fluid pipes 40, 50 and condenser 20 may be only 20~30% of that in the radiator designed with one gaseous working fluid pipe. With the flow resistance reduction, the working fluid in the loop thermosyphon can be circulated at higher efficiency. The cooling capacity of the device is increased.

According to the embodiment, providing two or more gaseous working fluid pipes 40, 50 can improve the circulation of the working fluid in the radiator and thus the cooling efficiency of the radiator, even if the linear velocity of the gaseous working fluid was reduced. This overcomes conventional concept that reduced linear velocity of the gaseous working fluid would cause degraded circulation and thus decreased cooling efficiency.

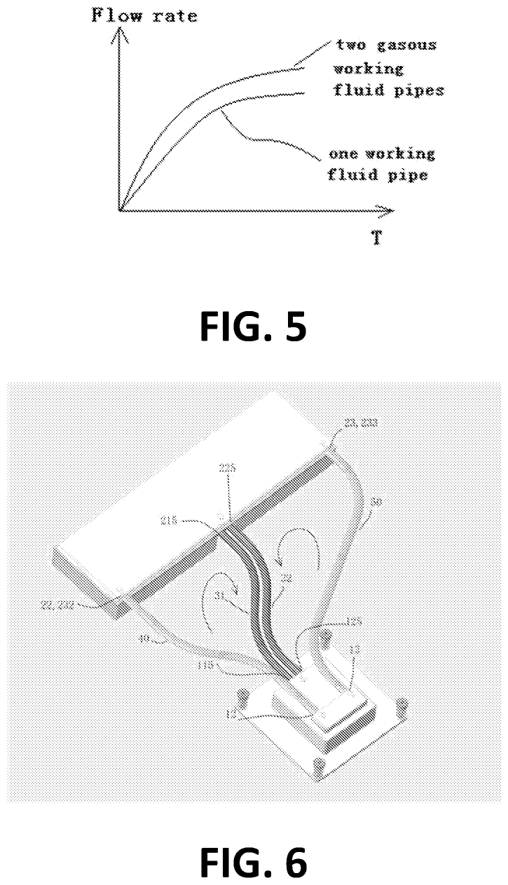

FIG. 5 shows exemplar improvement of a radiator with two gaseous working fluid pipes 40, 50 in comparison with that with a single gaseous working fluid pipe. Herein, it is assumed that all of the gaseous working fluid pipes in the radiator has the same section area. From the plots in FIG. 5, with the temperature increasing, the flow rate within the radiator with two gaseous working fluid pipes 40, 50 increases more rapidly than the radiator with one gaseous working fluid pipe.

The liquid working fluid pipe 30 and the gaseous working fluid pipes 40, 50 may be made of suitable material to achieve fluid seal during conveying the working fluid. The liquid working fluid pipe 30 and the gaseous working fluid pipes 40, 50 may be made by the same material or by different materials, as long as they can implement their own functions of conveying working fluid and maintaining pressure in the circulation loop thermosyphon. The liquid working fluid pipe 30 and the gaseous working fluid pipes 40, 50 may be flexible so as to facilitate installation of the radiator.

According to embodiments of the present disclosure, the liquid working fluid pipe 30 and the gaseous working fluid pipes 40, 50 together with the evaporator 10 and the condenser 20 may form more than one circulation loop thermosyphons, such as two circulation loop thermosyphons in the embodiment as shown in FIG. 1. In an embodiment, when the evaporator 10 is heated by a heat source, it heats/vapors the liquid working fluid in the evaporator 10, such as evaporator cavity therein. Initially, the liquid working fluid is heated but is not transformed into the gaseous working fluid. In the embodiment, the condenser 20 is located higher than the evaporator 10. In other words, the condenser 20 includes a base plate 210 and at least one surface of the base plate 210 is higher than a bottom of the evaporator 10. For example, a top surface of the base plate 210 is higher than the bottom of the evaporator 10. Due to gravity, the heated working fluid in the evaporator 10 rises, and leaves the evaporator cavity, for example through evaporator outlets 12, 13 in top of the evaporator cavity, into the gaseous working fluid pipes 40, 50, and the liquid working fluid in the condenser 20 at lower temperature flows towards, actually downwards, the evaporator 10. By this way, the circulation of the working fluid may initiates.

In an embodiment, the working fluid may be water, alcohol, carbinol, or any of other coolants which can be evaporated to gaseous phase and condensed to liquid phase. Those skilled in the art may select a suitable coolant according to design specification.

In an embodiment, with continuous heating, the liquid working fluid in the evaporator 10 may be evaporated into the gaseous working fluid with an expanded volume at a higher temperature, so that a pressure in the evaporator cavity may be increased. In this situation, the gaseous working fluid may rise and is expelled under the increased pressure out of the evaporator cavity into the gaseous working fluid pipes 40, 50, and the liquid working fluid in the condenser 20 may flow towards the evaporator 10.

In the embodiment, the evaporator 10 may have two or more evaporator outlets 12, 13 on top of the evaporator 10, to which the two or more gaseous working fluid pipes 40, 50 are respectively connected. By this way, as the heated working fluid will rise, it is more easily to enter the evaporator outlets 12, 13 than the working fluid at lower temperature, such as the working fluid from the condenser 20 via the liquid working fluid pipe 30, even the heated working fluid is still liquid. The evaporator cavity may be a single structure defining a single cavity therein, and the evaporator outlets 12, 13 may be opened on the top of the evaporator cavity in a single structure. In another embodiment, the evaporator outlets 12, 13 may be located upper part of the evaporator cavity in a single structure, such as side wall of the evaporator cavity.

According to the embodiments of the present disclosure, two or more circulation loop thermosyphons are provided to improve cooling efficiency. FIGS. 1, 6 and 7 respectively show several examples so as to easily understand the concept of the present disclosure.

FIG. 1 shows an embodiment of a radiator of the present disclosure, in which one liquid working fluid pipe 30 connected to a condenser outlet 25 in the middle of the condenser 20 and two gaseous working fluid pipes 40, 50 connected respectively to condenser inlets 22, 23 of the condenser 20 at both ends thereof are provided. In the embodiment, the two gaseous working fluid pipes 40, 50 comprise a first gaseous working fluid pipe 40 and a second gaseous working fluid pipe 50. The condenser inlets 22, 23 comprise a first condenser inlet 22 and a second condenser inlet 23. As shown in FIG. 1, the first gaseous working fluid pipe 40, the first condenser inlet 22, the condenser outlet 25, and the liquid working fluid pipe 30 constitute a part of a first circulation loop thermosyphon, and the second gaseous working fluid pipe 50, the second condenser inlet 23, the condenser outlet 25 and the liquid working fluid pipe 30 constitute a part of the second circulation loop thermosyphon. The arrows in the respective circulation loop thermosyphon schematically illustrate the cycling direction of the working fluid therein. In the embodiment, the gaseous working fluid is split into two gaseous working fluid pipes 40, 50 so that the linear velocity of the gaseous working fluid is reduced and thus flow resistance in the gaseous working fluid pipes and condenser is greatly reduced. The achieved circulation speed of the loop thermosyphon and cooling capacity of the radiator are increased. Further, in the embodiment, the gaseous working fluid is inputted into the condenser from two ends and flows from two ends to the middle of the condenser, thereby circulation of the working fluid increasing, comparing with a circulation of the working fluid from one end to the other end in a radiator with a single gaseous working fluid pipe. In FIG. 1, the condenser outlet 25 is schematically shown in middle of the condenser 20, but the shown structure will not limit the configuration of the condenser outlet 25. In the following embodiment, the condenser outlet 25 will be described in detailed.

FIG. 6 shows another embodiment of the present disclosure, in which two liquid working fluid pipes 31, 32 connected to condenser outlets 215, 225 in the middle of the condenser 20 and two gaseous working fluid pipes 40, 50 respectively connected to condenser inlets 232, 233 at either end of the condenser 20 are provided. The condenser outlets 215, 225 comprise a first condenser outlet 215 and a second condenser outlet 225, and the two liquid working fluid pipes 31, 32 comprise a first liquid working fluid pipe 31 connected to the first condenser outlet 215 and a second liquid working fluid pipe 32 connected to the second condenser outlet 225. The condenser inlets 232, 233 comprise a first condenser inlet 232 and a second condenser inlet 233, and the two gaseous working fluid pipes 40, 50 comprise a first gaseous working fluid pipe 40 connected to the first condenser inlet 232 and a second gaseous working fluid pipe 50 connected the second condenser inlet 233. In the embodiment, the first gaseous working fluid pipe 40, the first condenser inlet 232, the first condenser outlet 215 and the first liquid working fluid pipe 31 constitute at least part of a third circulation loop thermosyphon, and the second gaseous working fluid pipe 50, the second condenser inlet 233, the second condenser outlet 225 and the second liquid working fluid pipe 32 constitute at least part of a fourth circulation loop thermosyphon. The arrows in the respective circulation loop thermosyphon schematically illustrate the cycling direction of the working fluid therein.

Similar to the embodiment as shown in FIG. 1, the gaseous working fluid is split into two gaseous working fluid pipes 40, 50 and thus the flowing velocity of the vapor working fluid is reduced and thus flowing resistance in the gaseous fluid pipes and condenser is greatly reduced. Further, the liquid working fluid is also split into two liquid working fluid pipes 31, 32 and thus the flowing resistance can be further reduced. By this configuration, the entire cooling efficiency can be further increased.

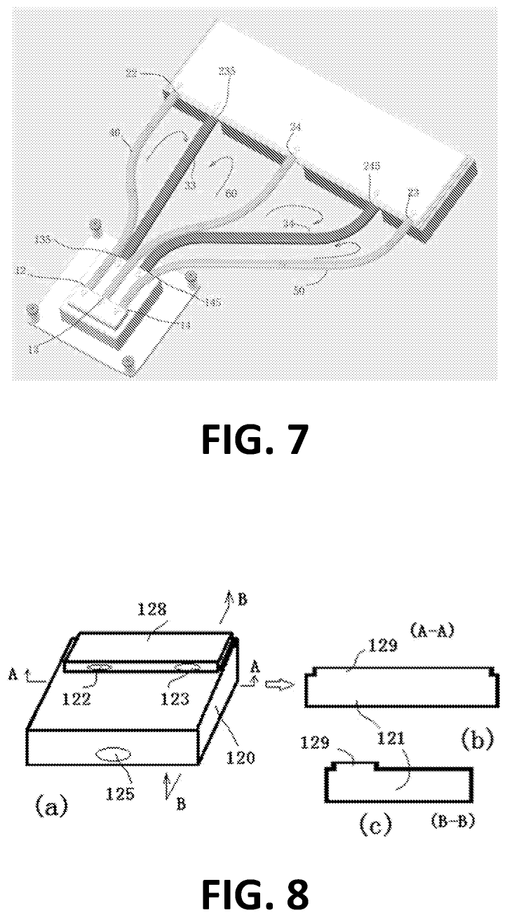

FIG. 7 shows still another embodiment of the present disclosure, in which two liquid working fluid pipes 31, 32 connected to condenser outlets 215, 225 in the parts near either end of the condenser 20 and three gaseous working fluid pipes 40, 50, two of which are connected to condenser inlets 22, 23 at either end and one of which is connected to condenser inlet 24 in the middle of the condenser 20, are provided. The condenser outlets 235, 245 comprise a first condenser outlet 235 and a second condenser outlet 245, and the two liquid working fluid pipes 33, 34 comprise a first liquid working fluid pipe 33 connected to the first condenser outlet 235 and a second liquid working fluid pipe 34 connected to the second condenser outlet 245. The condenser inlets 22, 23, 24 comprise a first condenser inlet 22, a second condenser inlet 23 and a third condenser inlet 24, and the three gaseous working fluid pipes 40, 50, 60 comprise a first gaseous working fluid pipe 40 connected to the first condenser inlet 22, a second gaseous working fluid pipe 50 connected the second condenser inlet 23 and a third gaseous working fluid pipe 60 connected the third condenser inlet 24. In the embodiment, the first gaseous working fluid pipe 40, the first condenser inlet 22, the first condenser outlet 235 and the first liquid working fluid pipe 33 constitute at least part of a fifth circulation loop thermosyphon, the second gaseous working fluid pipe 50, the second condenser inlet 23, the second condenser outlet 245 and the second liquid working fluid pipe 34 constitute at least part of a sixth circulation loop thermosyphon, the third gaseous working fluid pipe 60, the third condenser inlet 24, the first condenser outlet 235 and the first liquid working fluid pipe 33 constitute at least part of a seventh circulation loop thermosyphon, and the third gaseous working fluid pipe 60, the third condenser inlet 24, the second condenser outlet 245 and the second liquid working fluid pipe 34 constitute at least part of an eighth circulation loop thermosyphon. The arrows in the respective circulation loop thermosyphon schematically illustrate the cycling direction of the working fluid therein.

Different from the embodiment as shown in FIG. 6, in the embodiment as shown in FIG. 7, the gaseous working fluid is split into three gaseous working fluid pipes 40, 50, 60 and thus the linear velocity of the gaseous working fluid is further reduced and thus flow resistance in the gaseous fluid pipes and condenser is greatly reduced. Further, the liquid working fluid is also split into two liquid working fluid pipes 33, 34 and thus the flow resistance can be further reduced. Thus the entire cooling efficiency can be further increased.

The present application may include embodiments in other manners than those as shown in FIGS. 1, 6 and 7. Those skilled in the art will envisage all embodiments according to the above description. It is also known the number of the liquid working fluid pipes 31, 32 or 33, 34 and that of the gaseous working fluid pipes 40, 50 and/or 60 described in the above embodiments are not intended to limit a relationship between them. The locations of the above outlets and inlets in the condenser and the evaporator may be adjusted without being limited by the illustrated embodiments.

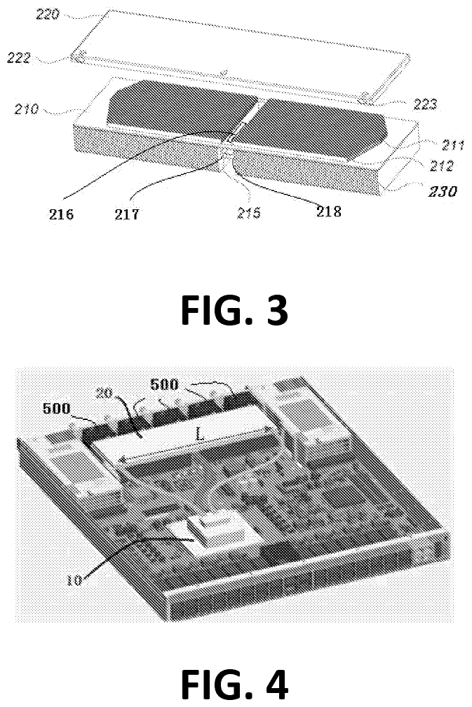

The radiator in the present disclosure includes evaporator 10 and condenser 20, and they are further described in the following content by reference to FIGS. 2 and 3. FIGS. 2 and 3 merely show examples of the evaporator 10 and condenser 20, but are not limiting the structure and design of them. On the contrary, those skilled in the art can envisage all structures and designs of the present invention based on the following description.

FIG. 2 shows an exploded isometric view of an embodiment of the evaporator 10 of the radiator. In an embodiment, the evaporator 10 includes an evaporator housing main body 120 defining a first cavity 121 therein, and a raised portion 128, on the top of the evaporator housing main body 120, defining a second cavity 129 therein in fluid communication with the first cavity 121, referring to FIG. 8. In other words, the evaporator 10 has an evaporator cavity in a two-cavity structure, including the first cavity 121 and the second cavity 129. FIG. 8(b) and 8(c) schematically show the two-cavity structure in sectional views respectively cut in two directions A-A and B-B perpendicular to each other. The two-cavity structure does not limit the first cavity 121 and the second cavity 129 to be connected to each other by conduit, but means the evaporator cavity may be considered to have two parts or two regions. In the embodiment, at least one evaporator inlet 125 is disposed in the evaporator housing main body 120 of the evaporator 10, and the raised portion 128 is disposed with two or more evaporator outlets 122, 123. By this way, the evaporator outlets 122, 123 are located at a higher level than the evaporator inlet 125. In the embodiment, the gaseous working fluid pipes 40, 50 are connected to the evaporator outlets 122, 123 of the raised portion 128 and the liquid working fluid pipe 30 is connected to the evaporator inlet 125 of the evaporator housing main body 120, so that the liquid working fluid enters the first cavity 121, and after heated, leaves the evaporator 10 from the second cavity 129 in liquid or gaseous state. In the embodiment, when the liquid working fluid is heated to the gaseous working fluid in the first cavity 121, the gaseous working fluid rises and enters the second cavity 129 of the raised portion 128, and is expelled out of the raised portion via the evaporator outlets 122, 123, and at the same time, the liquid working fluid at lower temperature enters the first cavity 121 of the evaporator 10 via the evaporator inlet 125.

In the embodiment as shown in FIG. 2, a horizontal section area of the raised portion 128 is less than that of the evaporator housing main body 120. FIG. 2 shows the raised portion 128 is located at a side, away from the evaporator inlet 125, on the top of the evaporator housing main body 120. However, in some embodiments, the raised portion 128 may be disposed on any location on the top of the evaporator housing main body 120.

According to embodiment of the present disclosure, the second cavity 129 can also function as a collector for the heated working fluid/gaseous working fluid. That is, the second cavity 129 contains substantively the working fluid or gaseous working fluid at highest temperature, different from the first cavity 121, in which the liquid working fluid at relative low temperature or a mixture of liquid working fluid and gaseous working fluid is filled. Thus, the second cavity 129 is more likely to output substantively gaseous working fluid, instead of a mixture of liquid and gaseous working fluids. Moreover, due to the configuration of the raised portion 128 functioning collection, the pressure in the gaseous working fluid pipes 40, 50 will be more stable.

However, it is noted that the two-cavity structure is not necessary for the present application, and an embodiment in which the raised portion 128 and the evaporator housing main body 120 have the same horizontal section can be considered as a single-cavity evaporator 10 with increasing height. In such increased-height structure, the gaseous working fluid pipes 40, 50 are connected to the evaporator outlets 12, 13 on the top thereof.

FIG. 2 also shows a plurality of evaporation fins 111 of the evaporator 10, which are configured to space from each other within the first cavity 121 of the evaporator housing main body 120. As shown in FIG. 2, the plurality of evaporation fins 111 are divided into sections by several channels 112 so that the liquid working fluid is capable of passing through the one or more channel 112 and then flowing to a space between adjacent ones of the plurality of evaporation fins 111. An extension direction of the channels 112 and that of the space are not parallel to each other. In FIG. 2, the evaporation fins 111 are parallel to each other, defining the extension direction of the space therebetween. The channels 112 cross the evaporation fins 111 and thereby, the channels 112 are in fluid communication with each of the spaces. The liquid working fluid entering the evaporator 10 can flow along the channels 112, and then flows into each of the spaces, achieving sufficiently contacting to the evaporation fins 111 and improving heat transferring efficiency.

FIG. 2 further illustrates all the channels 112 open towards the evaporator inlet 125 of the evaporator housing main body 120. In this structure, the liquid working fluid entering the first cavity 121 will flow directly into the channels 112, with least flow resistance. However, it is appreciated that the shown structure is not limiting the design of the channel, and the channel may be configured in any dimension as long as they extends and cross the space between adjacent ones of the evaporator fins 111.

FIG. 3 shows an exploded isometric view of a condenser 20 according to an embodiment of the present disclosure. In the embodiment, as shown in FIG. 3, the condenser 20 may include a base plate 210 and a cover plate 220, which are connected together to define a condenser cavity 214. In the embodiment, the condenser cavity 214 has a substantially rectangle shape, like the cover plate. The condenser 20 has a plurality of internal condensation fins 211 configured to space from each other within the condenser cavity 214. The condenser 20 shown in FIG. 3 is partially disassembled to expose its internal condensation fins 211. The condenser 20 also has a plurality of external condensation fins 230 configured to space from each other outside of the condenser cavity 214. The plurality of internal condensation fins 211 and the plurality of external condensation fins 230 are mounted respectively on opposite side surface of the base plate 210 of the condenser 20. The plurality of internal condensation fins 211 are arranged in a polygonal shape, different from the rectangle of the cover plate 220 or the based plate 210. At the corner of the condenser cavity 214 in a shape of rectangle, no condensation fins are provided to form a margin region. The margin region is enclosed by the cover plate, the side of the polygonal shape and the sides of the rectangle. The margin region looks like a cut area 212 of the polygonal shape of the arranged condensation fins. In other words, the polygonal shape has at least one side oblique with respect to the side of the rectangle to form the cut area 212. In an embodiment, at least one side of the polygonal shape is oblique with respect to a direction in which the plurality of internal condensation fins 211 are arranged. Due to the cut area 212, the working fluid in the condenser cavity 214 can flow sufficiently and is easy circulated within the condenser cavity 214, thereby achieving sufficient contact between the working fluid and the internal condensation fins.

In an embodiment, the condenser 20 includes a condenser outlet 215 in the base plate 210 and the at least one liquid working fluid pipe 30 is connected to the condenser outlet 215. In the embodiment, the liquid working fluid pipe 30 is located below the base plate 210 and thus is located among the plurality of external condensation fins 230.

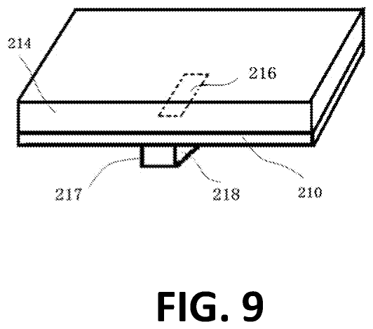

In the embodiment as shown in FIGS. 3 and 9, the base plate 210 is illustrated to be provided with an elongated through hole 216, and a dropped cavity 218 is provided under and communicated with the elongated through hole 216. As shown in FIG. 9, the based plate may include a dropped portion 217, in which the dropped cavity 218 is defined. The dropped cavity 218 and the through hole may be formed as a whole cavity at a level below the condenser cavity 214. In the embodiment, the condenser outlet 215 is open towards the dropped cavity 218 in the dropped portion 217 of the based plate, as shown in FIG. 3. It is noted that the elongated through hole 216 is shown in FIG. 3 to extend by about half of the width of the base plate 210 as an example. The elongated through hole 216, however, may have more or less length extending along the width of the base plate 210. The condenser outlet 215 is provided below the base plate 210, and thus the liquid working fluid pipe 30 connected to the condenser outlet 215 is located among the external condensation fins 230.

In an embodiment not shown, the base plate 210 may has a recess, which provides the dropped cavity 218, and does not have the dropped portion 217 as described above. The recess, i.e., the dropped cavity 218 in the recess, is communicated to the condenser cavity 214. It is appreciated that the dropped cavity 218 may be considered as a part of the condenser cavity 214, which is located at a dropped level in comparison with other part of the condenser cavity 214. In the embodiment, the condenser outlet 215 may be disposed in the based plate 210, coupled to the dropped cavity 218. In an embodiment, the condenser outlet 25, 215 is provided below the base plate 210, and thus is located among the external condensation fins 230.The condenser 20 having the condenser cavity 214 and the dropped cavity 218 is advantageous that the condensed liquid working fluid can be accumulated in the dropped cavity 218 so that the liquid working fluid entering the liquid working fluid pipe 30 contains gaseous working fluid as less as possible, thereby improving the cooling efficiency. In addition, the mixture of the gaseous working fluid and liquid working fluid contains turbulence flow in the condenser cavity 214. However, the liquid condensed liquid working fluid accumulated in the dropped cavity 218 involves substantially no turbulence flow, and thus the liquid working fluid, when entering the liquid working fluid pipe 30, will bring substantially no turbulence flow to the liquid working fluid pipe 30. The radiator can be improved with enhanced reliability and efficiency.

Another aspect of the present disclosure provides an electronic apparatus. The electronic apparatus includes the radiator as described above. In the embodiment, the electronic apparatus may be a filter, a communication device, terminal device, a user device, a user terminal, a wireless device, a wireless terminal, a vehicle mounted devices, a computing power equipment, a computer, a processor, a radar or any other suitable device. The electronic apparatus includes at least one heat source. The evaporator 10 of the radiator is configured to contact the heat source to absorb heat from the heat source, so as to cool the heat source. In an embodiment, the electronic apparatus may include a fan 500 and the fan 500 is configured to adjacent to the condenser 20 of the radiator. For example, FIG. 4 shows an exemplar electronic apparatus, in which a set of fans including five fans 500 is provided. As shown in FIG. 4, the set of fans has a total length in the lengthwise direction L of the condenser 20. The total length is substantially same to or less than the length L of the condenser 20. For example, the condenser 20 may be located adjacent to the fans 500 so that the fans 500 can blow air towards the external condensation fins. It is noted that a plurality of fans, such as five fans shown in FIG. 4, are generally provided in an electronic apparatus, and in this disclosure, the fan should be understood to include one fan or a plurality of fans as required.

In the electronic apparatus, the condenser 20 and the evaporator 10 are arranged to space away from each other, and are connected via the liquid working fluid pipe 30 and the gaseous working fluid pipes 40, 50. Due to the flexibility of the liquid working fluid pipe 30 and the gaseous working fluid pipes 40, 50, the evaporator 10 and the condenser 20 may be facilitated to be mounted on the heat source and fan respectively, without limiting installing locations of the heat source and fan in the electronic apparatus. Further, the external fins on a side of the base plate 210 of the condenser 20 is advantageous to allow the based plate of condenser 20 and thus the condenser cavity 214 to be located on a raised level relative to the evaporator 10, thereby promoting loop thermosyphons in the radiator.

The disclosure has been described with reference to embodiments and drawings. It should be understood that various modifications, alternations and additions can be made by those skilled in the art without departing from the spirits and scope of the disclosure. Therefore, the scope of the disclosure is not limited to the above particular embodiments but only defined by the claims as attached and equivalents thereof.

1-19. (canceled)

20. A radiator comprising:
an evaporator arranged to evaporate liquid working fluid in the evaporator to form gaseous working fluid;
a condenser configured to condense the gaseous working fluid into the liquid working fluid;
at least one liquid working fluid pipe arranged to couple the condenser with the evaporator and to convey the liquid working fluid from the condenser to the evaporator; and
two or more gaseous working fluid pipes arranged to couple the condenser with the evaporator and to convey the gaseous working fluid from the evaporator to the condenser,
wherein the at least one liquid working fluid pipe, the two or more gaseous working fluid pipes, the evaporator, and the condenser are arranged to form more than one circulation loop thermosyphon.

21. The radiator according to claim 20, wherein the condenser comprises a base plate having at least one surface higher than a bottom of the evaporator.

22. The radiator according to claim 21, wherein the evaporator comprises:
an evaporator housing main body defining a first cavity therein and having at least one evaporator inlet; and
a raised portion on the top of the evaporator housing main body, wherein the raised portion defines a second cavity therein that is in fluid communication with the first cavity and has two or more evaporator outlets,
wherein the two or more gaseous working fluid pipes are connected to respective ones of the two or more evaporator outlets, such that the gaseous working fluid in the second cavity is expelled to the two or more gaseous working fluid pipes via the respective evaporator outlets connected thereto.

23. The radiator according to claim 22, where a horizontal section area of the raised portion is less than a horizontal area of the evaporator housing main body.

24. The radiator according to the claim 22, wherein the at least one liquid working fluid pipe is connected to the evaporator inlet of the evaporator housing main body and arranged to convey the liquid working fluid to the first cavity.

25. The radiator according to claim 22, wherein:
the at least one liquid working fluid pipe comprises one liquid working fluid pipe connected to a condenser outlet in the middle of the condenser; and
the two or more gaseous working fluids pipes comprise two gaseous working fluid pipes connected to condenser inlets at respective ends of the condenser.

26. The radiator according to claim 25, wherein:
the two gaseous working fluid pipes comprise a first gaseous working fluid pipe and a second gaseous working fluid pipe;
the condenser inlets comprise a first condenser inlet and a second condenser inlet;
the first gaseous working fluid pipe, the first condenser inlet, the condenser outlet, and the one liquid working fluid pipe constitute at least part of a first circulation loop thermosyphon; and
the second gaseous working fluid pipe, the second condenser inlet, the condenser outlet and the one liquid working fluid pipe constitute at least part of a second circulation loop thermosyphon.

27. The radiator according to claim 22, wherein:
the at least one liquid working fluid pipe comprises two liquid working fluid pipes connected to respective two condenser outlets in the middle of the condenser; and
the two or more gaseous working fluid pipes comprise two gaseous working fluid pipes respectively connected to respective two condenser inlets at either end of the condenser.

28. The radiator according to claim 27, wherein:
the condenser outlets comprise a first condenser outlet and a second condenser outlet;
the two liquid working fluid pipes comprise a first liquid working fluid pipe connected to the first condenser outlet and a second liquid working fluid pipe connected to the second condenser outlet;
the condenser inlets comprise a first condenser inlet and a second condenser inlet; and
the two gaseous working fluid pipes comprise a first gaseous working fluid pipe connected to the first condenser inlet and a second gaseous working fluid pipe connected the second condenser inlet.

29. The radiator according to claim 28, wherein:
the first gaseous working fluid pipe, the first condenser inlet, the first condenser outlet and the first liquid working fluid pipe constitute at least part of a third circulation loop thermosyphon, and
the second gaseous working fluid pipe, the second condenser inlet, the second condenser outlet and the second liquid working fluid pipe constitute at least part of a fourth circulation loop thermosyphon.

30. The radiator according to claim 22, wherein the condenser comprises:
a condenser cavity,
a plurality of internal condensation fins mounted on a first surface of the base plate and spaced apart from each other within the condenser cavity, and
a plurality of external condensation fins mounted on a second surface of the base plate opposite to the first surface and spaced apart from each other outside of the condenser cavity.

31. The radiator according to claim 30, wherein the plurality of internal condensation fins are arranged in a polygonal shape, so as to have a cut area with respect to the condenser and such that at least one side of the polygonal shape is oblique with respect to a direction in which the plurality of internal condensation fins are arranged.

32. The radiator according to claim 30, wherein the condenser comprises a condenser outlet in the base plate of the condenser, so that the at least one liquid working fluid pipe is connected to the condenser outlet among the plurality of external condensation fins.

33. The radiator according to claim 32, wherein the base plate includes a dropped cavity integrated with the condenser cavity, and the condenser outlet is open towards the dropped cavity.

34. The radiator according to claim 22, wherein the evaporator comprises a plurality of evaporation fins spaced apart from each other within the first cavity of the evaporator housing main body.

35. The radiator according to claim 34, wherein the plurality of evaporation fins are divided into sections by one or more channels such that the working fluid is capable of passing through the one or more channels to spaces between adjacent ones of the plurality of evaporation fins.

36. The radiator according to claim 35, wherein one or more of the following applies:
an extension direction of the one or more channels is non-parallel to an extension direction of the spaces between adjacent ones of the plurality of evaporation fins;; and
the spaces between adjacent ones of the plurality of evaporation fins cross and are in fluid communication with at least one of the one or more channels.

37. The radiator according to claim 35, wherein at least one of the one or more channels opens towards the evaporator inlet of the evaporator housing main body.

38. An electronic apparatus comprising the radiator according to claim 20.

39. The electronic apparatus according to claim 38, further comprising one or more fans arranged adjacent to the condenser of the radiator, wherein the condenser has a dimension larger than or equal to a total dimension of the one or more fans in a lengthwise direction of the condenser.
